(19) United States
(12) Patent Application Publication
(10) Pub. No.: US 2002/0197810 A1
(43) Pub. Date: Dec. 26, 2002

(54) Mosfet having a variable gate oxide thickness and a variable gate work function, and a method for making the same

(75) Inventors: Hussein I. Hanafi, Basking Ridge, NJ (US); Suk H. Ku, Beacon, NY (US); Meikei Ieong, Wappingers Falls, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY (US)

(21) Appl. No.: 09/886,681

(22) Filed: Jun. 21, 2001

(51) Int. Cl. H01L 21/3205; H01L 21/4763; H01L 21/336

(52) U.S. Cl. 438/330; 438/300; 438/592; 438/283; 257/330

(57) ABSTRACT

A transistor has a gate with a variable work function and a gate oxide layer with variable thickness. The gate oxide layer has an area of reduced thickness at its center, and the gate is made from central and peripheral portions. The central portion is formed over the central (thinner) portion of the gate oxide layer, and the peripheral portions are formed over the thicker areas of the gate oxide layer. The gate, gate oxide layer, and two source/drain regions may be formed in a damascene trench for improved performance, and lightly doped drain (LDD) regions preferably extend from the source/drain regions in overlapping relationship with the peripheral portions of the gate. Additionally, a method for making an asymmetrical transistor is presented, which involves applying a gate oxide layer on a semiconductor layer in contact with a sidewall structure. A first spacer made of a gate material is formed on the structure and gate oxide layer. An LDD region is then formed in the semiconductor layer, using the first spacer as a mask for alignment purposes. This is followed by formation of a second spacer on the gate oxide layer in overlapping relationship with the LDD region. The second spacer contacts the first spacer and is made of a gate material, and thus the first and second spacers collectively form the gate of the transistor. Final processing steps are performed to finish the device.

### BACKGROUND OF THE INVENTION

1. Field of the Invention

This invention generally relates to integrated circuits, and more particularly to methods of making Metal-Oxide-Semiconductor Field Effect Transistors (MOSFETs) with improved performance characteristics.

2. Description of the Related Art

Integrated circuit chips have become a virtual necessity in modem life. They are used, for example, as general-purpose processors and storage devices in computers, they are used to perform specific applications in televisions, digital cameras and medical devices, and within the last decade they have enabled the existence of a variety of hand-held wireless products that have gained widespread appeal. Regardless of the use, designers of integrated circuit chips share a common challenge, that of increasing integration density while at the same time making them operate more efficiently. While designers strive to accomplish both goals, this is not always possible.

The basic building block of most integrated circuits is the MOSFET(Metal -Oxide-Semiconductor Field Effect Transistor). MOSFET is a three terminal device ( source, drain, and gate terminals). The region between source and drain under the gate oxide is called channel. Most of the current flows from drain to source via channel region. MOSFET is a switch which operates by modulating conductivity of the channel region by applying voltage at the gate terminal.

As the integration density of an integrated circuit increases, the size of individual MOSFET decreases. One of the main industry trend is to scale all the transistor dimensions accordingly. Gate oxide thickness, which is one of the main design parameter, is scaled down as the transistor dimensions are scaled down. As the gate oxide thickness is reduced, gate to source/drain leakage due to quantum mechanical tunneling increases. This adversely affects off-state leakage current of the MOSFET as well as gate oxide reliability. In addition, a reduction in gate oxide thickness results in an increase in gate to source/drain capacitance. This adversely affects switching speed of the MOSFET.

There is therefore a need for a method that will allow a reduction in the gate oxide thicknesses in the channel region of its transistors without producing a corresponding increase in the gate to source/drain leakage and capacitance of those transistors.

Another known approach for reducing gate to source/drain leakage and capacitance in a transistor is the so-called bird's beak technique. This is used to develop a variable gate oxide thickness. To implement this technique, a nitride masking layer blocks oxidation during a LOCOS process, and as a result an oxide layer grows near the edges of the masking layer. The thickness of the oxide layer gradually increases as it moves away from the edge of the masking layer, thereby resembling the shape of a “bird's beak,” hence its name. If the gate conductor is on top of the tapering region, it will have variable gate oxide thickness across the channel.

The bird's beak approach has at least two drawback. First, it does not precisely control the thickness of the gate oxide during fabrication. This may lead to inconsistencies which can detract from the expected performance of the finished device. Second, the Bird's beak approach does not have the freedom to make oxide thickness of any sequence (i.e., thick-thin-medium-thin is not possible with Bird's beak).

Another way in which transistor designers have attempted to increase performance is by using transistors with a variable gate work function. The gates of MOSFET transistor are often made of polysilicon. One way to create variable work function is to add germanium to the polysilicon. In such transistors, the work function of the gate can be modulated by appropriately establishing the mole fraction of the germanium in the gate. U.S. Pat. No. 6,180,499 discloses making a semiconductor device having a variable work function in this manner.

Advantages of using a variable-work-function transistor in integrated circuit devices have been recognized. Perhaps most significantly, a variable-work-function allows the effective channel length of the transistor to be modulated between the on and off-state. If the effective channel length in the off- state is longer than the on state, it is possible to achieve improved Ion/Ioff ratio, which will give enhanced performance. This is described in an article by Sandip Tiwari entitled “Straddle-Gate Transistor: Changing MOSFET Channel Length Between Off- and On-State Towards Achieving Tunneling-Defined Limit of Field Effect,” published in IEDM (1998).

In view of the foregoing considerations, it is clear that there is a need for an integrated circuit device having a transistor with a variable work function that is more efficient than those previously known.

### SUMMARY OF THE INVENTION

It is one object of the present invention to provide a transistor which has improved performance compared with conventional transistors.

It is another object of the present invention to achieve the aforementioned object by providing a transistor which has both a variable work function and a variable gate oxide thickness. By combining these features, the transistor of the present invention is able to reduce gate oxide thickness of the channel region without realizing a substantial increase in gate to source/drain leakage and gate to source/drain overlap capacitance.

It is another object of the present invention to provide a method for making a transistor of the aforementioned type wherein formation of the variable gate oxide thickness is more precisely controlled compared to conventional methods, thereby producing a more reliable transistor.

It is another object of the present invention to provide a method for making an asymmetrical transistor with variable gate oxide thickness and variable gate work function with self-alignment with respect to the formation of an source/drain LDD implant.

The foregoing and other objects of the invention are achieved by providing a transistor which has a gate with a variable work function and a gate oxide layer with variable thickness. The gate oxide layer has an area of reduced thickness at its center, and the gate is made from central and peripheral portions. The central portion of the gate is formed over the central (thinner) portion of the gate oxide layer, and the peripheral portions are formed over the thicker areas of the gate oxide layer. The gate, gate oxide layer, and two source/drain regions may be formed in a damascene trench for improved performance, and lightly doped drain (LDD) regions preferably extend from the source/drain regions in overlapping relationship with the peripheral portions of the gate. In addition to these features, the central and peripheral portions of the gate may be formed from different materials. Also, the thinner area of the gate oxide layer may have a dielectric constant different from the remaining thicker portions. If desired, halo regions may be implanted in the semiconductor material surrounding the LDD regions.

The present invention is also a method for forming a transistor having the aforementioned features. In accordance with one embodiment, the method begins by forming a trench in a semiconductor layer, applying a first gate oxide layer in the trench, and then forming first spacers on respective sidewalls of the trench. This is followed by the formation of second spacers on the first spacers. The first spacers are preferably made from an insulating material and the second spacers are made from gate material, such as polysilicon. Once the second spacers are formed, an aperture is etched through the gate oxide layer in the area between the second spacers. The second spacers are used as masks during the etch to control the formation and alignment of the aperture in the gate oxide layer. The use of the second spacers as masks advantageously makes the method of the present invention self-aligning.

After the aperture is formed, a second gate oxide layer is grown in the aperture. In order to make the thickness of the gate oxide layer variable, the second gate oxide layer is grown to a thickness which is less than the thickness of the first gate oxide layer. A second gate material is then deposited between the second spacers and over the second gate oxide layer. Preferably, the second gate material is different from the material used to form the second spacers. Together, the second spacers and the second gate material form the gate of the transistor. The source and drain regions with LDD extensions and/or halos are implanted into the semiconductor substrate after the gate is formed. The top portion of the gate may then be silicidized for improved performance.

The present invention is also a method for making an asymmetrical transistor in accordance with steps that include providing a structure on a layer of semiconductor material and then applying a gate oxide layer on the semiconductor layer in contact with a sidewall of this structure. The structure may be any conventionally used in semiconductor device fabrication which is removable by an etch or other process. The method continues by forming a first spacer made of a gate material on the structure and gate oxide layer. An LDD region is then formed in the semiconductor layer, using the first spacer as a mask for alignment purposes. This is followed by forming a second spacer on the gate oxide layer in overlapping relationship with the LDD region. The second spacer contacts the first spacer and is made of a gate material, and thus the first and second spacers collectively form the gate of the transistor. In two final steps, the structure is removed and source/drain regions are formed in the semiconductor layer on either side of the gate, with one of the source/drain regions contacting the LDD region. Preferably, the first and second spacers are made from different gate materials.

### BRIEF DESCRIPTION OF THE DRAWINGS

FIG. 1 is a diagram of a preferred embodiment of a first type of a transistor in accordance with the present invention.

FIG. 2 is a diagram showing an initial step in a preferred embodiment of the method for making the first type of transistor in accordance with the present invention.

FIG. 3 is a diagram showing a subsequent step of the preferred embodiment of the method of the present invention.

FIG. 4 is a diagram showing a subsequent step of the preferred embodiment of the method of the present invention.

FIG. 5 is a diagram showing a subsequent step of the preferred embodiment of the method of the present invention.

FIG. 6 is a diagram showing a subsequent step of the preferred embodiment of the method of the present invention.

FIG. 7 is a diagram showing a subsequent step of the preferred embodiment of the method of the present invention.

FIG. 8 is a diagram showing a subsequent step of the preferred embodiment of the method of the present invention.

FIG. 9 is a diagram showing a subsequent step of the preferred embodiment of the method of the present invention.

FIG. 10 is a diagram showing a subsequent step of the preferred embodiment of the method of the present invention.

FIG. 11 is a diagram showing a subsequent step of the preferred embodiment of the method of the present invention.

FIG. 12 is a diagram showing a subsequent step of the preferred embodiment of the method of the present invention.

FIG. 13 is a diagram showing a subsequent step of the preferred embodiment of the method of the present invention.

FIG. 14 is a diagram showing a subsequent step of the preferred embodiment of the method of the present invention.

FIG. 15 is a diagram showing a subsequent step of the preferred embodiment of the method of the present invention.

FIG. 16 is a diagram showing a subsequent step of the preferred embodiment of the method of the present invention.

FIG. 17 is a diagram showing a subsequent step of the preferred embodiment of the method of the present invention.

FIG. 18 is a diagram showing an initial step in a preferred embodiment of the method of the present invention for making an asymmetrical MOSFET

FIG. 19 is a diagram showing a subsequent step of this method of the present invention.

FIG. 20 is a diagram showing a subsequent step of this method of the present invention.

FIG. 21 is a diagram showing a subsequent step of this method of the present invention.

FIG. 22 is a diagram showing a subsequent step of this method of the present invention.

FIG. 23 is a diagram showing a subsequent step of this method of the present invention.

### DESCRIPTION OF THE PREFERRED EMBODIMENTS

The present invention is, in one respect, an improved MOSFET transistor which combines the features of a variable gate oxide thickness with a variable work function. The present invention is also a method of making such a transistor with self-alignment which allows smaller gate dimension compared with that conventionally known. The present invention is also a method for making an asymmetrical MOSFET with variable gate oxide thickness and variable gate work function, which is also self-aligned, and achieves gate structures which are much shorter than can be achieved using conventional methods for making asymmetrical transistors.

FIG. 1 is a diagram of a preferred embodiment of the transistor 1 of the present invention. This transistor includes a gate 2 and a gate oxide layer 3 located in a damascene trench 4 formed in a substrate which includes source and drain regions 5 and 6. The source and drain regions are preferably implanted into the substrate in accordance with known techniques, including those mentioned in the discussion of the method which follows. Projecting from the source and drain regions are extensions 7 and 8 often referred to as lightly doped drain (LDD) regions. These LDD regions are advantageous because they disperse the electric field of the source and drain regions. This, in turn, reduces electric field strength and, commensurately, the generation of high-energy particles, all of which reduce an undesirable phenomenon known as channel hot carrier effect.

In operation, when voltage it applied to the gate structure, a channel forms between the extensions to provide an electrical path for connecting the source and drain. Positioned adjacent the extensions within the body of the substrate are halo regions 9. These regions have a conductivity type opposite to that of the source and drain and respectively serve to increase the dopant concentration in the channel edge region and bottom of the source and drain, thereby reducing the likelihood of punch through.

The gate and gate oxide layer are formed within the trench at a position over the LDD extensions and the channel region. As shown, the gate oxide layer 3 is thicker in areas 10 where there is overlap with the source and drain extensions. The gate oxide layer then becomes thinner in a central, non-overlapping area 12, which corresponds to the channel region of the device. Thus, the transistor of the present invention has a variable gate oxide layer which advantageously lowers overlap capacitance between the gate and the source and drain, and which further reduces leakage current between the gate and these two elements.

The gate 2 is formed to include inner and outer gate portions 14 and 15. The inner gate portion 14 has a width which is delimited by the width of the thinner region of the gate oxide layer. The outer gate portions 15 are formed on the sides of the inner gate portion and preferably have widths commensurate with the widths of the thicker gate oxide portions. The height of both gate portions extend above the trench.

In accordance with a preferred embodiment of the present invention, gate portions 14 and 15 are made from materials which have different work functions. The inner and outer gate portions may be made, for example, from a metal or polysilicon. Because the gate portions are made from different materials, the overall gate structure of the transistor will have a variable work function (i.e., variable threshold voltages) which translates into added advantages.

The combined features of a variable thickness gate oxide layer and a variable work function gate layer allow the transistor of the present invention to outperform its conventional counterparts in at least two ways. First, by using a gate with a variable work function, the channel surface potential of the transistor may be modulated along the channel. This advantageously reduces sub-threshold current by allowing the effective channel length to be modulated between on- and off-states. Second, using a variable gate oxide thickness advantageously reduces gate to source/drain leakage in the off-state, as well as a reduced source/drain overlap capacitance without sacrificing on-state current.

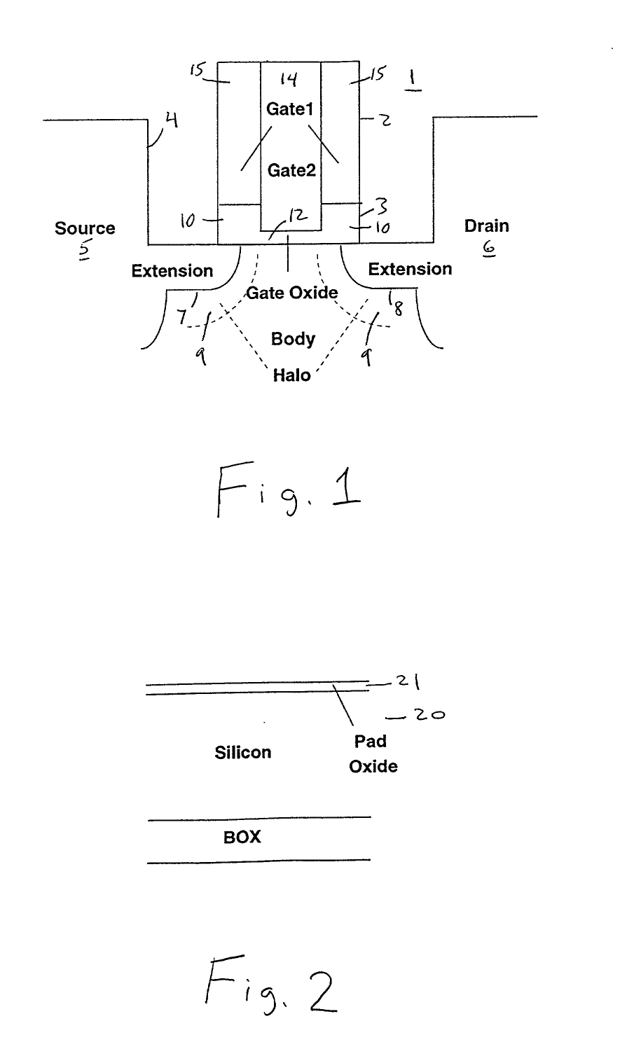

Referring to FIG. 2, a method for making a transistor having a variable work function and variable gate oxide thickness in accordance with a preferred embodiment of the present invention begins by growing a pad oxide layer 21 on a substrate 20 made of silicon. Preferably, the pad oxide layer is thermally grown on the silicon to a thickness sufficient to relieve stress between the silicon and nitride.

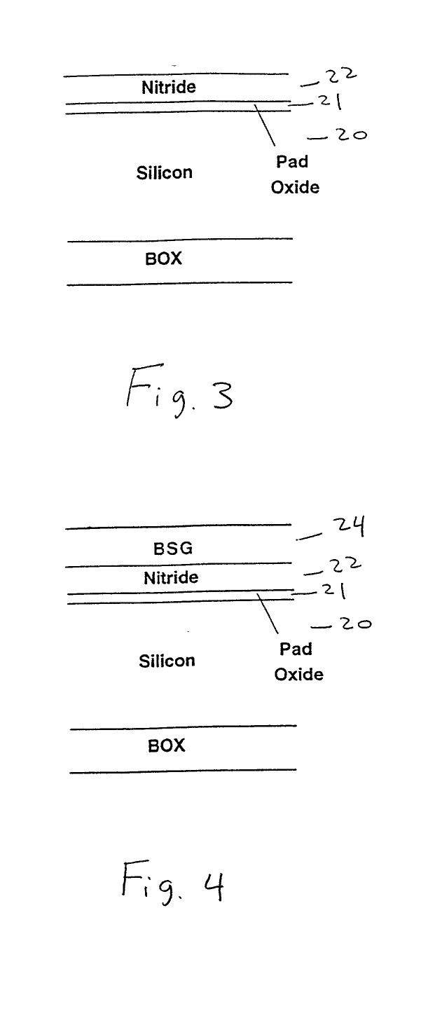

In a second step of the method, shown in FIG. 3, a nitride layer 22 (e.g., silicon nitride) is deposited on top of the pad oxide layer using, for example, plasma enhanced chemical vapor deposition (PECVD). Low-pressure chemical vapor deposition (LPCVD) or other known processes may alternatively be used to form the nitride layer. Formation of the nitride layer over the pad oxide layer is desirable because the pad oxide layer serves to reduce stress between the nitride mask and the semiconductor substrate.

In a third step of the method, shown in FIG. 4, an insulating layer 24 made, for example, of boron-doped glass (BSG) is deposited over the nitride layer using, for example, plasma enhanced chemical vapor deposition.

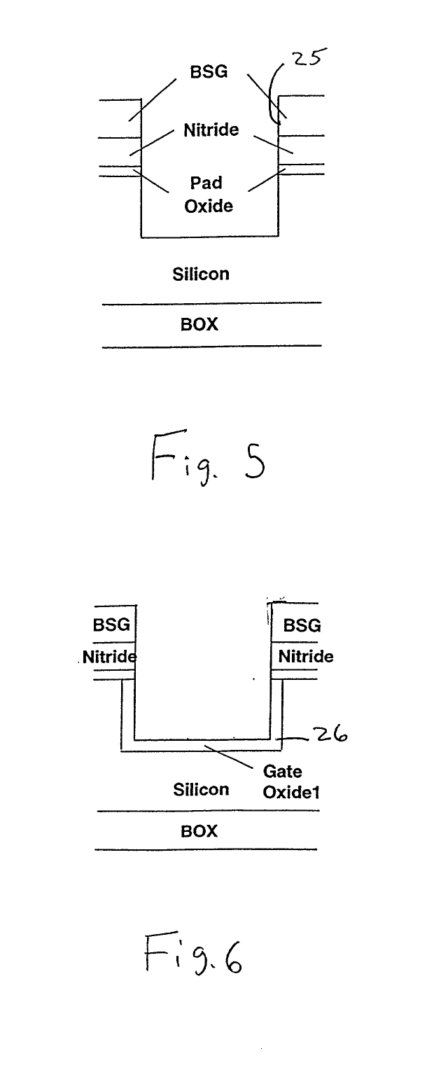

In a fourth step, shown in FIG. 5, a damascene trench 25 is patterned all the way down to the silicon substrate. Preferably, the trench extends a predetermined depth into the substrate to accommodate formation of the source and drain regions, to be discussed in greater detail below. The trench may be patterned using any of a number of known techniques including but not limited to lithography and reactive ion etching.

In a fifth step, shown in FIG. 6, a relatively thick gate oxide layer 26 is grown on the portion of the sidewalls and bottom of the silicon substrate in which the trench is formed. The oxide may be silicon dioxide, oxynitride, nitride, or a gate dielectric material may be used. Because oxide layer 26 will inherently grow only in the silicon, formation of layer 26 on the nitride and BSG layers is prevented. The thickness of this layer will substantially correspond to the thick portions of the gate oxide layer in the finished transistor.

In a sixth step, shown in FIG. 7, a double-spacer process is performed where first spacers 27 are insulators and second spacers 28 are materials from which the outer gate portions of the variable work function transistor will be formed. This double-spacer process may be performed using conventional techniques, for example, as disclosed in U.S. Pat. No. 5,866,462.

Formation of second spacers 28 define the width of the gate portions of the transistor of the present invention. Specifically, the distance between the second spacers delimit the width of the inner gate portion and the width of the second spacers themselves respectively delimit the widths of the outer gate portions. This distance may be varied but in any instance the second spacers must not contact one another.

Formation of the second spacers using this process advantageously allows the gate structure of the variable work function transistor of the present invention to be more precisely formed in comparison with conventional methods. For example, by precisely controlling the thicknesses of the second spacers particularly at the surface of the gate oxide layer, the width of the overall gate structure is controlled to match a desired dimension. Such precision cannot be achieved using conventional methods.

Also, the present invention has the advantage of being a self-aligned process. Conventional processes are not self-aligned. They, instead, perform lithographic alignment which has proven to be complicated and imprecise. In contrast, the present invention is self-aligning, in that once the trench is formed the other features of the device, including the spacers, are self-aligned to the trench. As a result, by through the invention the portions of the gate with different work functions are automatically aligned with one other. As a result, a more precise alignment results. Use of the double-spacer process in the manner contemplated by the invention also allows sub-lithographic dimensions for the portions of the gate with different work functions, since they are limited by the spacer-formation process not lithographic alignment. This advantage is also not realized using conventional methods.

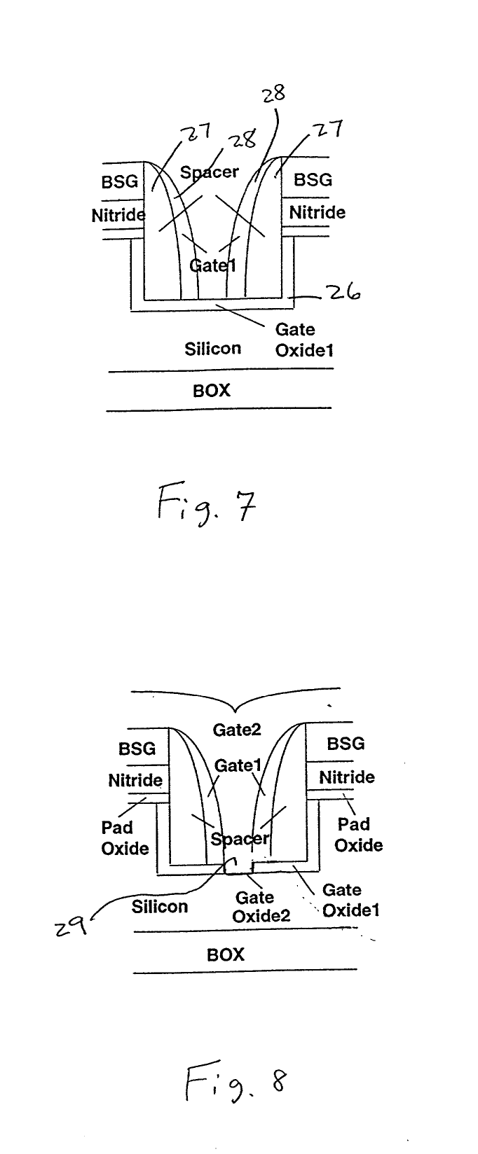

In a seventh step, shown in FIG. 8, an aperture 29 is etched in thick oxide layer 26 using, for example, a wet etch or reactive ion etching process. During this etching step, the spacers are used as making layers. The result is to form aperture 29 which passes through oxide layer 26 down to the underlying silicon substrate.

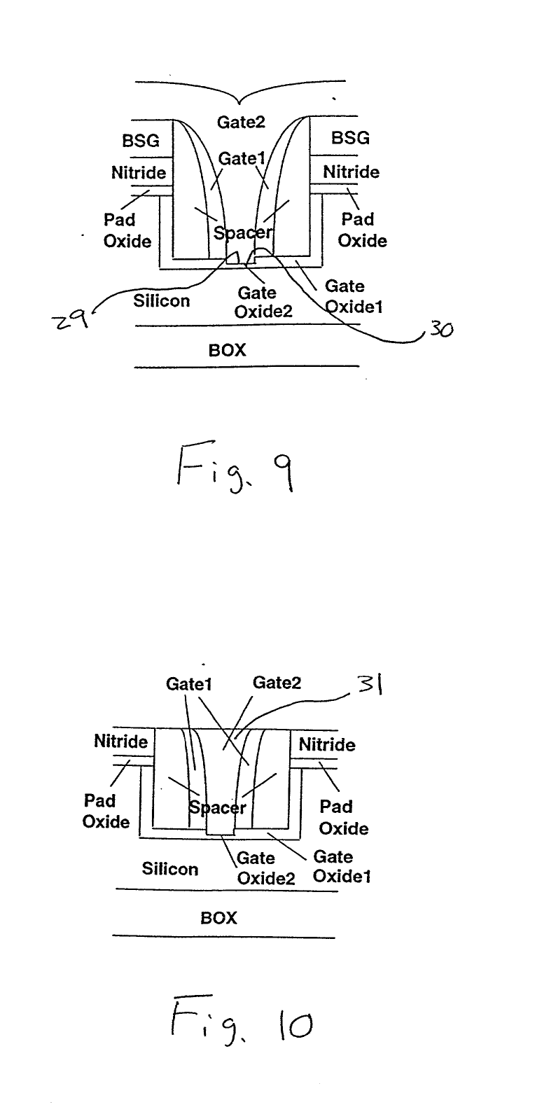

In an eighth step, shown in FIG. 9, a second gate oxide layer 30 is thermally grown to a predetermined thickness in aperture 29. The thickness of oxide layer 30 is less than the thickness of oxide layer 26 in order to form what will eventually form the variable thickness of the gate oxide layer of the present invention. If desired, the second gate oxide layer and oxide layer 26 may have different dielectric constants. This will give more flexibility in designing the variable gate work function profile in accordance with the present invention, and also will result in different capacitances at the thicker and thinner portions which may result in a reduction of leakage. Silicon dioxide, oxynitride, or nitrides are specific materials which may be used to form the second gate oxide layer.

In a ninth step, shown in FIG. 10, the area between the spacers is filled with gate material 31 which will become the internal gate portion of the transistor. Known deposition techniques may be used to perform this step. In order for the transistor of the present invention to have a variable work function, gate material 31 is selected to be different from the material used to form second spacers 28. Conductive materials such as metal or polysilicon may be used to form the gate materials. Selection of the work function for the gate material depends specifically on the transistor design. A desired work function may be selected for a target threshold voltage by taking into consideration factors such as oxide thickness, substrate doping, and amount of fixed charge.

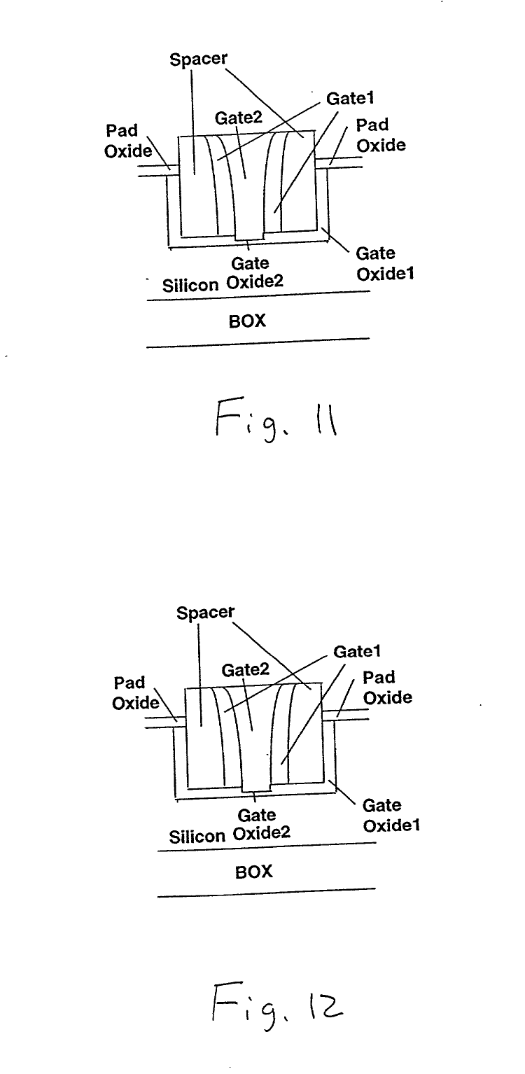

In a tenth step, shown in FIG. 11, portions of gate material 31, second spacers 28, and first spacers 27, and the entirety of insulating (e.g., BSG) layer 24 are removed down to the upper surface of the nitride layer. Preferably, this material is removed by a chemical mechanical polishing (CMP) process because such a process leaves a very smooth, planar surface which has proven to improve performance of the finished transistor. Other planarizing and/or material removal processes may be used to perform this step, if desired.

In an eleventh step, shown in FIG. 12, the nitride layer 22 is removed to expose the pad oxide layer. Removal of the nitride layer may be accomplished by a selective etch process which, for example, may be a wet etch.

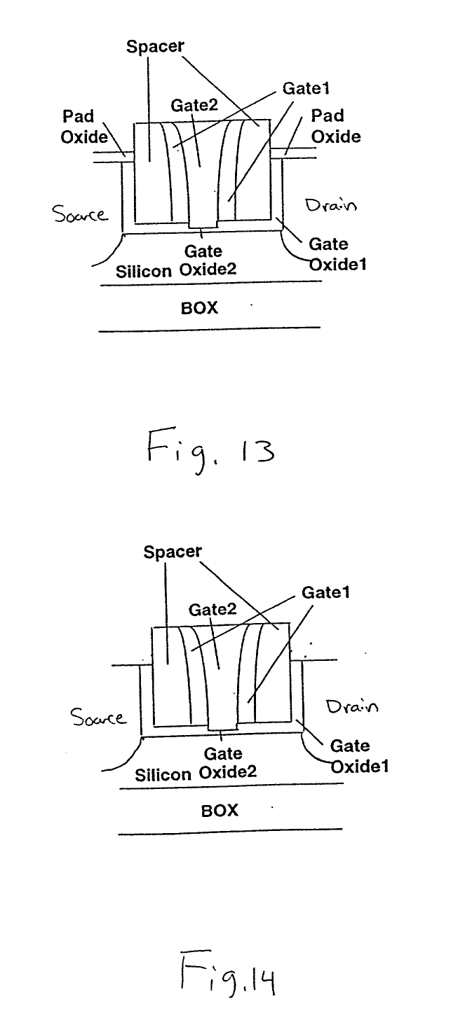

In a twelfth step, shown in FIG. 13, source and drain regions 32 and 33 are implanted into the substrate at respective positions beneath the pad oxide layer. The ions (e.g., boron, phosphorus, arsenic, indium) forming the source and drain implants are implanted to a depth which extends below the level of the gate oxide layers so as to allow a channel to be formed in the silicon substrate after subsequent steps of the method are performed and a voltage is applied to the gate.

In a next step, shown in FIG. 14, the pad oxide layer is removed using, for example, a known wet etching process.

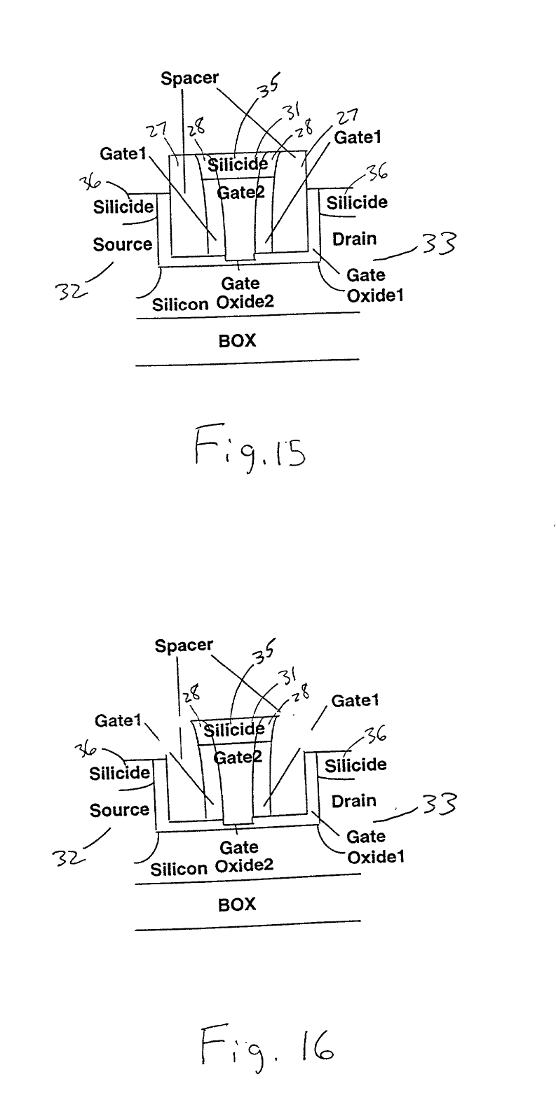

In a next step, shown in FIG. 15 the exposed portions of gate material 31 and gate material 28 are silicided, for example, with a metal such as titanium or cobalt. During this process, the metal atoms diffuse into and react with the gate material. Because side portions of the gate materials are exposed down to the silicon substrate, gate materials 28 and 31 are silicided to this depth. If desired, however, the depth of silicidation of the gate materials may be controlled to be a different depth. By way of example, the silicidation may be performed by blanket-sputtering titanium onto the exposed gate materials, followed by rapid thermal annealing. This results in the formation of a transistor gate having a top portion 35 with improved bulk conductivity. It is also noted that the exposed portions 36 of the silicon substrate surface are also silicided along with the gate materials.

In a next step, shown in FIG. 16, the first spacer 27 is removed from the outer walls of the second spacer 28, which now serves as the gate material corresponding to the outer gate portions of the transistor of the present invention. The first spacers may be removed using conventional techniques, which include but are not limited to a selective wet etch.

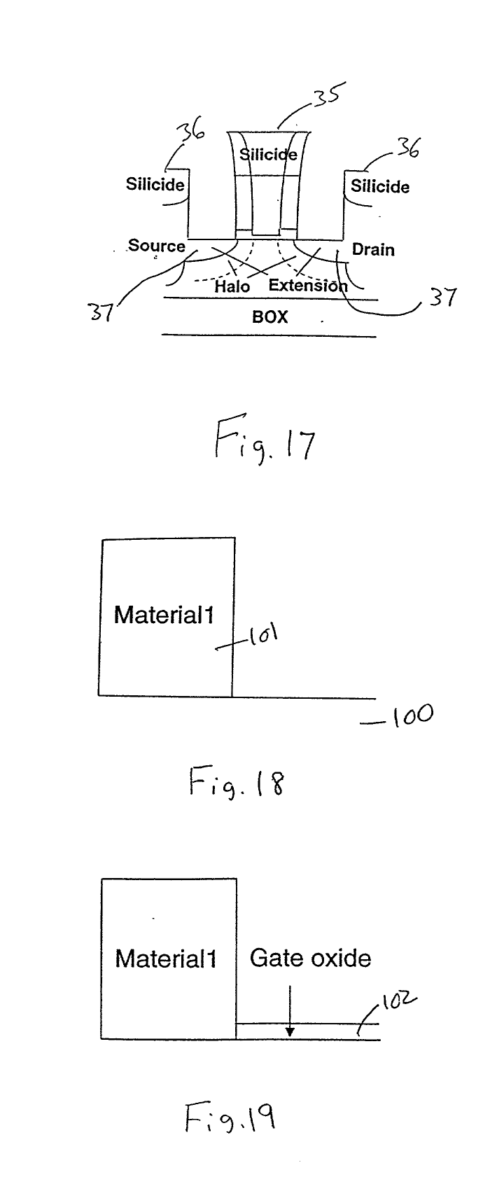

In a next step, shown in FIG. 17, LDD extensions 37 for the source and drain regions are implanted, along with halo regions 38 that extend a predetermined distance around the LDD extensions. A known ion implantation process may be used to perform this step.

As a result of the foregoing steps, an improved transistor is formed having a variable thickness gate oxide layer and a variable work function having all the aforementioned advantages over conventional damascene transistors. In addition, the present method used to form this transistor is beneficial because it is self-aligned, which means that the masking layer that blocks the implant of the LDD extension regions is aligned to the gate without any misalignment. This translates into improved process control and a more efficiently designed transistor.

Alternative embodiments of the transistor of the present invention may be contemplated. For example, the embodiment of FIG. 1 has two gate portions and two gate oxide layer thickness. If desired, the number of gate thicknesses and gate portions may be increased to meet the particular application of the transistor. By using three or more gate portions, for example, the number of work functions of the transistor may be increased.

Similarly, constructing the gate oxide layer to have three or more thicknesses may have the advantageous effect of further reducing gate to source/drain leakage and capacitance. In such an embodiment, the number of gate oxide layer thicknesses may correspond to the number of gate portions in the transistor, where the width of each gate oxide layer delimits the width of a respective gate portion.

Referring to FIG. 18, a preferred embodiment of the method of the present invention for making an asymmetrical MOSFET begins by forming a structure 101 on a substrate 100 made of silicon or another semiconductor material. Structure 101 may be a resist material, a masking layer, or other types of formations.

In a second step, shown in FIG. 19, a gate oxide layer 102 is grown on the substrate at an area adjacent structure 101 using known techniques. The gate oxide layer may be silicon dioxide, nitride, oxynitride, or any other insulating material.

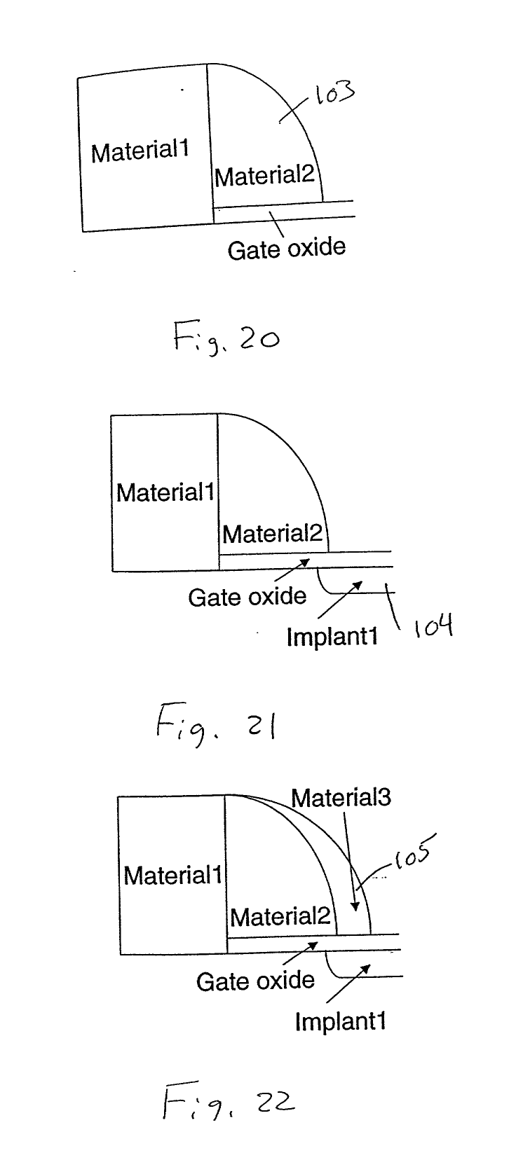

In a third step, shown in FIG. 20, a first spacer 103 is formed along the sidewall of structure 101 and on top of gate oxide layer 102 using a conventional spacer-forming process. The spacer is formed from a material such as an oxide or nitride.

In a fourth step, shown in FIG. 21, a source/drain extension (e.g., LDD) region 104 is implanted through the gate oxide layer and into the silicon substrate. Advantageously, first spacer 103 serves as a masking layer which prevents most of the LDD implant from penetrating into the substrate beneath spacer 103. As shown, only a portion of the LDD implant overlaps this spacer. Formation of the LDD region, thus, is self-aligning. As a result, the method of the present invention does not need to perform additional process steps which conventional methods are require to execute in order to align the LDD extensions with a gate layer of the transistor.

In a fifth step, shown in FIG. 22, a second spacer 105 is formed along the exposed surface of first spacer 103 and along a portion of the substrate which further overlaps the LDD implant. The gate layer is also made from gate material which may be the same or different from the material from which the first spacer is made. Once again, conventional techniques are used to form this spacer.

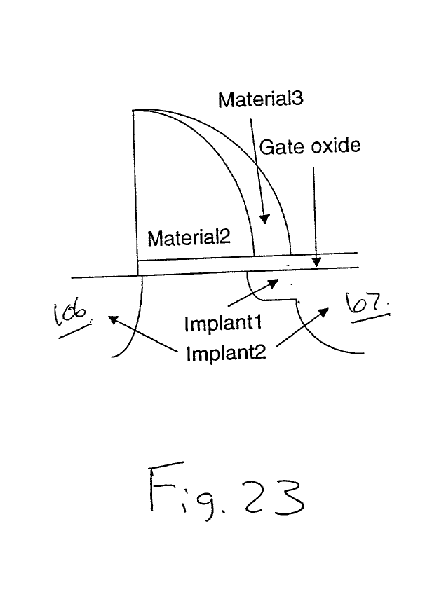

In a sixth step, shown in FIG. 23, structure 100 is removed, for example, by a selective etch, leaving the combined structure formed by the spacers.

In a seventh step, also shown in FIG. 23, source/drain regions 106 and 107 are implanted into the substrate using conventional techniques. Advantageously, the second spacer serves as a masking layer during this step which self-aligns source/drain region 107 to the gate structure that is now formed by the two spacers. This self-aligning process also ensures that source-drain region 107 contacts the LDD regions formed in previous steps of the method.

The method of the present invention for forming asymmetrical MOSFET outperforms conventional methods in a number of respects.

First, the method of the present invention forms a transistor having a gate structure which shorter than that attainable using conventional methods. This is because conventional methods are limited by photolithographic processes, but the present invention is not. More specifically, in order to create an asymmetrical MOSFET using conventional methods, the region where the implant is not needed is blocked by a masking layer which is aligned to the gate lithographically. Consequently, a reduction in gate length necessarily limits the ability to use such methods to fabricate the device substantially because of the limitation in alignment.

The present invention represents a significant improvement over conventional methods because it does not rely on lithography for alignment purposes. Instead, the method of the present invention is an inherently self-aligned process, which means that the masking layer which blocks the asymmetrical implant is aligned to the gate without any misalignment. Also, the gate length of a transistor produced by the method of the present invention is not limited by lithography. It is therefore possible to precisely control the fabrication of gate structures which are suitable for use in deep sub-micron devices.

In an alternative embodiment, the method of the present invention is used to form halo implants. These implants may be formed using any one of a number of conventional angled ion implantation processes. The angle may be selected to be any angle, and preferably lies within the range of from 0° to 90°. An asymmetric halo device formed in accordance with these steps are suitable for ballistic carrier transport.

Other modifications and variations to the invention will be apparent to those skilled in the art from the foregoing disclosure. Thus, while only certain embodiments of the invention have been specifically described herein, it will be apparent that numerous modifications may be made thereto without departing from the spirit and scope of the invention. For example, if desired the source and drain regions may be formed to overlap the gate material, thereby eliminating the need for LDD extensions.

We claim:

1. A transistor, comprising:
a layer of semiconductor material;
a source region in said layer;
a drain region in said layer and spaced from said source region;
a gate structure having a variable work function, said gate structure formed above said layer in which the source region and the drain region are located; and
a gate oxide layer between said gate structure and said layer, said gate oxide layer having a variable thickness.

2. The transistor of claim 1, wherein said gate oxide layer has a first area between a second area and a third area which are thicker than said first area.

3. The transistor of claim 2, wherein said gate structure includes a first gate portion between a second gate portion and a third gate portion, said first gate portion located above the first area of said gate oxide layer, and said second gate portion and said third gate portion disposed above the second area and third area of said gate oxide layer, respectively.

4. The transistor of claim 3, wherein said first gate portion and said second and third gate portions are made from different materials.

5. The transistor of claim 3, wherein the first area of said gate oxide layer has a dielectric constant different from the second and third areas of said gate oxide layer.

6. The transistor of claim 1, further comprising:
a first LDD region extending from said source region; and
a second LDD region extending from said drain region,
wherein said gate oxide layer and said gate structure at least partially overlap said first LDD region and said second LDD region.

7. The transistor of claim 6, further comprising:
halo regions located adjacent respective ones of said first LDD region and said second LDD region.

8. The transistor of claim 1, wherein said gate structure is formed in a damascene trench.

9. A transistor, comprising:
a source;
a drain;
a gate having a variable work function; and
a gate oxide layer between the gate and the source and drain, said gate oxide layer having variable thickness.

10. A method for making a transistor, comprising:
forming a trench which includes a layer of semiconductor material;
applying a first gate oxide layer in said trench;
forming first spacers on respective sidewalls of said trench;
forming second spacers on respective ones of said first spacers, said second spacers formed from a first gate material;
etching an aperture in an area of said gate oxide layer located between the second spacers, said etching step including using the second spacers as masking layers to control alignment of the aperture during etching, said aperture extending to the floor of said trench;
applying a second gate oxide layer in said aperture, said second gate oxide layer being thinner than said first gate oxide layer;
depositing a second gate material between said second spacers and over said second gate oxide layer, said first gate material and said second gate material forming a gate structure for the transistor;
forming a source region and a drain region adjacent said first gate oxide layer; and
removing said first spacers and said first gate oxide layer except a portion of said first gate oxide layer underlying said first gate material.

11. The method of claim 10, further comprising:
forming LDD extensions from said source region and said drain region, said LDD extensions overlapping said gate structure.

12. The method of claim 11, further comprising:
implanting halo regions around said LDD extensions.

13. The method of claim 10, further comprising:
polishing said gate structure back to a desired height.

14. The method of claim 13, further comprising:
silicidizing a top portion of said first gate material and said second material of said gate structure.

15. The method of claim 14, wherein said silicidizing step includes silicidizing sidewalls of said trench.

16. The method of claim 10, wherein said first material and said second gate material are different materials.

17. The method of claim 10, wherein said gate structure has a variable work function.

18. The method of claim 10, wherein said first gate oxide layer and said second gate oxide layer have different dielectric constants.

19. A method for forming a transistor, comprising:
applying a first oxide layer over semiconductor material;
forming a first insulator structure and a second insulator structure on said first oxide layer;
forming gate material on opposing walls of the first insulator structure and the second insulator structure, said forming step defining a space bounded by the gate material on said opposing walls and said first oxide layer;
using said gate material as masking layers to form an aperture in said first gate oxide layer;
forming a second oxide layer in said aperture, said second oxide layer being thinner than said first oxide layer;
filling said aperture with additional gate material, said gate material and said additional gate material forming a gate structure of the transistor;
removing said first insulator structure, said second insulator structure, and portions of said first oxide layer which are not under said gate material and said additional gate material; and
forming source and drain regions adjacent said gate structure.

20. The method of claim 19, wherein said gate material and said additional gate material are different materials.

21. The method of claim 19, wherein said gate structure has a variable work function.

22. The method of claim 19, further comprising:
forming LDD extensions on said source and drain regions, said LDD extensions overlapping said gate structure.

23. A method for forming a transistor, comprising:
applying a gate oxide layer on a layer of semiconductor material, said gate oxide layer having variable thickness;
forming a gate on said gate oxide layer, said gate having a variable work function; and
forming source and drain regions in said layer of semiconductor material at a location adjacent said gate.

24. The method of claim 23, wherein said step of forming source and drain regions includes:
forming LDD extensions on said source and drain regions, said LDD extensions overlapping said gate.

25. The method of claim 23, wherein said gate includes a first gate portion between a second gate portion and a third gate portion, said first gate portion made from a material different from said second gate portion and said third gate portion, and wherein said first gate portion is formed on a thinner area of said gate oxide layer on which said second gate portion and said third gate portion.

26. A method of making an asymmetrical MOSFET transistor, comprising:
providing a structure on a layer of semiconductor material;
applying a gate oxide layer on said semiconductor layer and in contact with a sidewall of said structure;
forming a first spacer on said structure and said gate oxide layer, said first spacer being made of a gate material;
forming an LDD region in said semiconductor layer by using said first spacer as a mask for aligning said LDD region in overlapping relationship with first spacer;
forming a second spacer on said gate oxide layer and in overlapping relationship with said LDD region, said second spacer contacting said first spacer and being made of a gate material, said first spacer and said second spacer forming a gate of the transistor;
removing said structure; and
forming source/drain regions in said layer of semiconductor material adjacent respective sides of said gate, one of said source/drain regions contacting said LDD region.

27. The method of claim 26, wherein the gate material of said first spacer and the gate material of said second spacer are different materials.
